(19) United States
(12) Patent Application Publication
(10) Pub. No.: US 2020/0152432 A1
(43) Pub. Date: May 14, 2020

(54) SUBSTRATE PROCESSING APPARATUS AND SUBSTRATE PROCESSING METHOD

(71) Applicant: TOKYO ELECTRON LIMITED, Tokyo (JP)

(72) Inventor: Masato KON, Miyagi (JP)

(73) Assignee: TOKYO ELECTRON LIMITED, Tokyo (JP)

(21) Appl. No.: 16/563,313

(22) Filed: Sep. 6, 2019

(30) Foreign Application Priority Data
Nov. 13, 2018 (JP) 2018-212606

(51) Int. Cl. H01J 37/32; H01L 21/67; B01D 53/14

(52) U.S. Cl. CPC H01J 37/32871; H01L 21/67069; B01D 2252/30; H01J 2237/334; B01D 53/1493

(57) ABSTRACT

A substrate processing apparatus includes a processing container configured to accommodate a substrate and perform a substrate processing that generates a byproduct that becomes a source of a harmful gas; and a liquid holder provided in an area of the processing container where the byproduct generated by the substrate processing adheres and configured to hold a liquid that adsorbs the byproduct.

### CROSS-REFERENCE TO RELATED APPLICATIONS

This application is based on and claims priority from Japanese Patent Application No. 2018-212606, filed on Nov. 13, 2018 with the Japan Patent Office, the disclosure of which is incorporated herein in its entirety by reference.

### TECHNICAL FIELD

The present disclosure relates to a substrate processing apparatus and a substrate processing method.

### BACKGROUND

Japanese Patent Laid-open Publication No. 2018-093064 describes a technique for etching a plurality of holes in a laminated film using plasma.

### SUMMARY

A substrate processing apparatus according to an aspect disclosed herein includes a processing container and a liquid. A substrate to be processed is disposed inside the processing container, and a substrate processing that generates a byproduct that becomes a source of a harmful gas is performed. The liquid is held in the area in the processing container to which the byproduct generated by the substrate processing adheres so as to adsorb the byproduct.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

FIG. 1 is a cross-sectional view illustrating a schematic configuration of a substrate processing apparatus according to an embodiment.

FIG. 2 is a perspective view illustrating an example of a schematic shape of a deposition shield according to an embodiment.

FIG. 3 is a view schematically representing an example of holding of an ionic liquid according to an embodiment.

FIG. 4 is a view schematically representing another example of holding of an ionic liquid according to an embodiment.

FIG. 5 is a view schematically representing another example of holding of an ionic liquid according to an embodiment.

### DETAILED DESCRIPTION

In the following detailed description, reference is made to the accompanying drawing, which form a part hereof. The illustrative embodiments described in the detailed description, drawing, and claims are not meant to be limiting. Other embodiments may be utilized, and other changes may be made without departing from the spirit or scope of the subject matter presented here.

Hereinafter, embodiments of a substrate processing apparatus and a substrate processing method disclosed herein will be described in detail with reference to the accompanying drawings. Meanwhile, the plasma processing apparatus and plasma processing method disclosed herein are not limited by the embodiments.

In the substrate processing apparatus, when a substrate to be processed is disposed in a processing container, the inside of the processing container is evacuated to a vacuum atmosphere, and the substrate processing is performed, byproducts which are the source of a harmful gas may be generated by a substrate processing. For example, when a plasma etching processing is performed on a substrate containing metal, byproducts are also generated as the etching processing progresses. Most of the byproducts are exhausted out of the processing container, but some of the byproducts adheres/deposits in the processing container. For example, when a substrate containing titanium (Ti) is etched using a gas containing chlorine or fluorine, titanium tetrachloride (TiCl₄) or titanium tetrafluoride (TiF₄) is generated as a byproduct. In addition, when Cl or F adheres to the area where Ti adheres in another process, TiCl₄ or TiF₄ is generated as a byproduct. TiCl₄ and TiF₄ are dangerous because they react with water to generate harmful gases such as hydrogen chloride (HCl) and hydrogen fluoride (HF), respectively. The processing container may be opened to the air atmosphere for, for example, maintenance. However, when the processing container is opened to the air atmosphere in the state in which TiCl₄ or TiF₄ is present therein, TiCl₄ or TiF₄ reacts with the moisture in the air atmosphere to generate HCl or HF. The HCl or HF not only causes a human injury, but also requires long-time evacuation after opening to the air atmosphere, which makes maintenance difficult. Accordingly, it is expected to suppress the generation of a harmful gas.

[Configuration of Substrate Processing Apparatus]

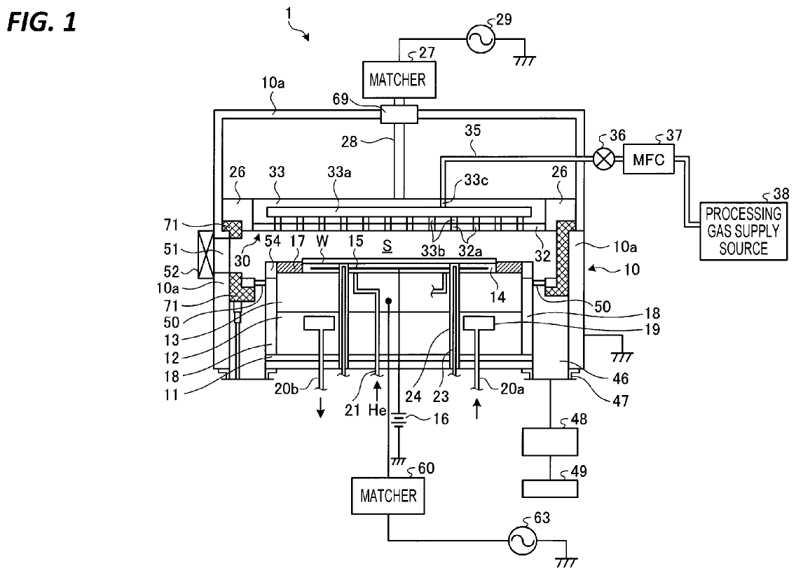

Next, a configuration example of the substrate processing apparatus according to the present embodiment will be described. FIG. 1 is a cross-sectional view illustrating a schematic configuration of a substrate processing apparatus according to an embodiment. In this embodiment, the case where the substrate processing apparatus is a plasma processing apparatus 1 that performs plasma etching on a semiconductor wafer W as a substrate to be processed is taken as an example. Meanwhile, the substrate processing apparatus is not particularly limited to the plasma processing apparatus 1.

The plasma processing apparatus 1 is configured as a capacitively coupled parallel plate plasma etching apparatus. The plasma processing apparatus 1 includes, for example, a cylindrical processing container 10 made of aluminum of which the surface is subjected to an alumite treatment (anodized). The processing container 10 is securely grounded. Meanwhile, the plasma processing apparatus 1 is not limited to a capacitively coupled parallel plate plasma etching apparatus, and may be any type of plasma processing apparatus such as an inductively coupled plasma (ICP) processing apparatus, a microwave plasma processing apparatus, or a magnetron plasma processing apparatus.

A cylindrical susceptor support 12 is disposed on the bottom portion of the processing container 10 via an insulating plate 11 made of, for example, ceramic. A susceptor 13 is disposed on the top of the susceptor support 12. The susceptor 13 is made of, for example, a conductive member such as, for example, aluminum, and functions as a lower electrode. For example, a semiconductor wafer W is placed on the susceptor 13 as a substrate to be processed.

An electrostatic chuck 14 for holding the semiconductor wafer W by electrostatic attraction is disposed on the top surface of the susceptor 13. The electrostatic chuck 14 is configured by sandwiching a sheet-shaped electrode plate 15 made of a conductive film between dielectric layers formed by a pair of dielectric members. A direct current (DC) power supply 16 is electrically connected to the electrode plate 15 via a connection terminal. The electrostatic chuck 14 attracts and holds a semiconductor wafer W by a Coulomb force or a Johnsen-Rahbek force caused by a DC voltage applied by the DC power supply 16.

In addition, in the susceptor 13 and the electrostatic chuck 14, through holes 24 accommodating pusher pins 23 that move the semiconductor wafer W up and down is formed in a portion where the semiconductor wafer W is held by attraction. The pusher pins 23 are connected to a motor (not illustrated) via a ball screw (not illustrated), and are movable from the top surface of the electrostatic chuck 14 due to the rotational movement of the motor converted to linear motion by the ball screw. Thus, the pusher pins 23 penetrate the electrostatic chuck 14 and the susceptor 13, and move up and down in the inner space. When the semiconductor wafer W is carried into and out of the processing container 10, the pusher pins 23 protrude from the electrostatic chuck 14 to separate the semiconductor wafer W from the electrostatic chuck 14 and raise the semiconductor wafer W upward. When an etching processing is performed on the semiconductor wafer W, the pusher pins 23 are accommodated in the electrostatic chuck 14.

A focus ring 17 made of, for example, silicon (Si) is disposed on the peripheral top surface of the susceptor 13 in order to improve etching uniformity. A cover ring 54 configured to protect the side of the focus ring 17 is disposed around the focus ring 17. The side surfaces of the susceptor 13 and the susceptor support 12 are covered with a cylindrical member 18 made of, for example, quartz (SiO₂).

Inside the susceptor support 12, for example, a coolant chamber 19 extending in the circumferential direction is disposed. A coolant having a predetermined temperature (e.g., cooling water) is circulated and supplied to the coolant chamber 19 from an external chiller unit (not illustrated) via pipes 20a and 20b. The coolant chamber 19 controls the processing temperature of the semiconductor wafer W on the susceptor 13 based on the temperature of the coolant.

Further, a gas supply line 21 is provided in the susceptor 13 and the electrostatic chuck 14. A heat transfer gas such as, for example, helium (He) gas, is supplied to the gas supply line 21 from a heat transfer gas supply mechanism (not illustrated). The heat transfer gas is supplied between the top surface of the electrostatic chuck 14 and the rear surface of the semiconductor wafer W via the gas supply line 21, so that the heat transfer between the semiconductor wafer W and the susceptor 13 is efficiently and uniformly controlled.

An upper electrode 30 is disposed above the susceptor 13 so as to face the susceptor 13. A space formed between the susceptor 13 and the upper electrode 30 functions as a plasma generation space S. An annular insulative shielding member 26 made of, for example, alumina (Al₂O₃) or yttria (Y₂O₃) is hermetically disposed between the upper electrode 30 and the side wall of the processing container 10.

The upper electrode 30 may be made of a low resistance conductor or semiconductor having low Joule heat, such as, for example, silicon. An upper radio-frequency power supply 29 is electrically connected to the upper electrode 30 via an upper feed rod 28 and an upper matcher 27. The upper radio-frequency power supply 29 outputs a radio-frequency voltage of a predetermined frequency of 13.5 MHz or more for plasma generation. For example, the upper radio-frequency power supply 29 outputs a radio-frequency voltage of 60 MHz. The upper matcher 27 matches a load impedance to the internal impedance of the upper radio-frequency power supply 29, and the upper radio-frequency power supply 29 functions such that the output impedance the load impedance apparently matches each other when plasma is generated in the processing container 10.

The side wall of the processing container 10 extends above the height position of the upper electrode 30 to form a cylindrical ground conductor 10a. The upper end portion of the cylindrical ground conductor 10a is electrically insulated from the upper feed rod 28 by a cylindrical insulating member 69.

The upper electrode 30 is supported in the upper portion of the processing container 10 via the insulative shielding member 26. The upper electrode 30 has an upper electrode plate 32 and an electrode support 33. The upper electrode plate 32 faces the plasma generation space S, and a plurality of gas ejection holes 32a are formed in the upper electrode plate 32. The upper electrode plate 32 is made of, for example, a semiconductor such as, for example, silicon or silicon carbide (SiC) or a low resistance conductor having a low Joule heat. The upper electrode 30 is capable of controlling the temperature. For example, the upper electrode 30 is provided with a temperature adjustment mechanism such as, for example, a heater (not illustrated) so that it is possible to control the temperature.

The electrode support 33 detachably supports the upper electrode plate 32. The electrode support 33 is made of, for example, a conductive material such as, for example, aluminum of which the surface is subjected to an alumite treatment. Inside the electrode support 33, a gas diffusion chamber 33a is provided. In the electrode support 33, a plurality of gas flow holes 33b communicating with the gas ejection holes 32a extend downward from the gas diffusion chamber 33a. In addition, the electrode support 33 is formed with a gas inlet 33c for introducing a processing gas into the gas diffusion chamber 33a. A gas supply pipe 35 is connected to the gas inlet 33c.

A processing gas supply source 38 is connected to the gas supply pipe 35 via an opening/closing valve 36 and a mass flow controller (MFC) 37. The processing gas supply source 38 includes gas sources of various gases used for plasma processing as processing gases, and supplies the various gases depending on the plasma processing. A gas supplied from the processing gas supply source 38 reaches the gas diffusion chamber 33a through the gas supply pipe 35, and is ejected into the plasma generation space S through the gas flow holes 33b and the gas ejection holes 32a.

An exhaust port 46 is provided in the bottom portion of the processing container 10. An automatic pressure control valve (hereinafter, referred to as an “APC valve”) 48 and a turbo molecular pump (hereinafter, referred to as “TMP”) 49 is connected to the exhaust port 46 through an exhaust manifold 47. The APC valve 48 and the TMP 49 cooperate to reduce the pressure of the plasma generation space S in the processing container 10 to a predetermined pressure-reduced state. In addition, an annular baffle plate 50 having a plurality of vent holes is disposed between the exhaust port 46 and the plasma generation space S so as to surround the susceptor 13. The baffle plate 50 suppresses the leakage of plasma from the plasma generation space S to the exhaust port 46.

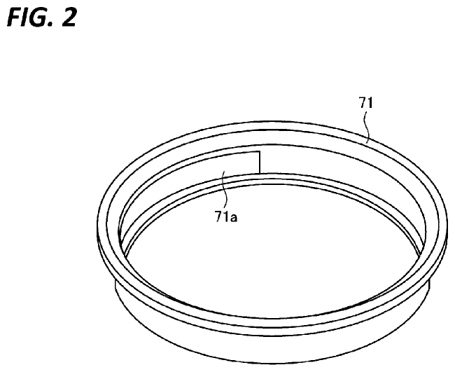

In addition, an opening 51 for loading/unloading a semiconductor wafer W is provided on the side wall of the processing container 10, and a gate valve 52 for opening and closing the opening 51 is disposed. In addition, a substantially cylindrical deposition shield 71 is disposed along the inner wall of the processing container 10 inside the processing container 10. FIG. 2 is a perspective view illustrating an example of a schematic shape of a deposition shield according to an embodiment. The deposition shield 71 has an opening 71a in the side wall thereof, and is disposed in the processing container 10 along the inner wall of the processing container 10 such that the opening 71a communicates with the opening 51 of the processing container 10. The deposition shield 71 functions as a protective member that suppresses the adhering of etching byproducts (deposit) to the inner wall of the processing container 10. In addition, the inner wall of the substantially cylindrical deposition shield 71 is coated with for example, yttria (Y₂O₃) by thermal spraying.

The semiconductor wafer W is loaded/unloaded by opening/closing the gate valve 52. Since the gate valve 52 is disposed outside the processing container 10, a space in which the opening 51 protrudes on the air atmosphere side is formed. The plasma processing apparatus 1 may be provided with a shutter for opening/closing the opening 71a of the deposition shield 71 in order to shield the space protruding to the air atmosphere side of the opening 51.

In the plasma processing apparatus 1, a lower radio-frequency power supply 63 is electrically connected to the susceptor 13 as the lower electrode via a lower matcher 60. The lower radio-frequency power supply 63 outputs a radio-frequency voltage of a predetermined frequency in the range of 2 to 27 MHz for bias for drawing in plasma. For example, the lower radio-frequency power supply 63 outputs a radio-frequency voltage of 2 MHz. Meanwhile, the plasma processing apparatus 1 may be configured as a lower two-frequency plasma apparatus that applies a radio-frequency voltage of a predetermined frequency for plasma generation to the susceptor 13. The lower matcher 60 matches a load impedance to the internal impedance of the lower radio-frequency power supply 63. The lower matcher 60 functions such that the internal impedance of the lower radio-frequency power supply 63 and the load impedance apparently match when plasma is generated in the plasma generation space S in the processing container 10.

Next, the flow of the etching processing by the plasma processing apparatus 1 according to the embodiment will be briefly described.

The plasma processing apparatus 1 causes the gate valve 52 to be opened. A semiconductor wafer W to be processed is loaded into the processing container 10 from the opening 51 by a transport apparatus (not illustrated) and placed on the susceptor 13. The plasma processing apparatus 1 causes the gate valve 52 to be closed after retracting the transport apparatus.

The plasma processing apparatus 1 operates the TMP 49 to reduce the pressure in the processing container 10 to a predetermined reduced-pressure state. In addition, the plasma processing apparatus 1 applies a DC voltage from the DC power supply 16 to the electrode plate 15 of the electrostatic chuck 14 so as to electrostatically attract the semiconductor wafer W to the susceptor 13.

The plasma processing apparatus 1 introduces processing gases used for etching from the processing gas supply source 38 into the processing container 10 at a predetermined flow rate and a flow rate ratio. In addition, the plasma processing apparatus 1 applies radio-frequency power of, for example, 60 MHz for plasma generation from the upper radio-frequency power supply 29 to the upper electrode 30 with predetermined power. Further, the plasma processing apparatus 1 applies radio-frequency power, such as, for example, 2 MHz for bias, from the lower radio-frequency power supply 63 to the lower electrode of the susceptor 13 with predetermined power. Thus, plasma is generated in the plasma generation space S between the upper electrode 30 and the susceptor 13. Ions in the plasma are drawn toward the semiconductor wafer W by the radio-frequency power from the lower radio-frequency power supply 63. Thus, the semiconductor wafer W is etched.

In the plasma processing apparatus 1, a byproduct which becomes the source of a harmful gas may be generated by a substrate processing during the etching processing. For example, when a plasma etching processing is performed on a substrate containing metal, byproducts are also generated as the etching processing progresses. For example, in the manufacture of a three-dimensionally stacked semiconductor memory such as a 3D-NAND flash memory, an etching processing is performed on a silicon layer and a metal layer of a substrate by the plasma processing apparatus 1. As the metal layer, for example, tungsten (W), titanium (Ti), aluminum (Al), ruthenium (Ru), or copper (Cu) is used. For example, when a substrate containing Ti is etched using a gas containing chlorine or fluorine, TiCl₄ or TiF₄ is generated as a byproduct. TiCl₄ and TiF₄ are dangerous because they react with water to generate harmful gases such as hydrogen chloride (HCl) and hydrogen fluoride (HF), respectively. The processing container 10 may be opened to the air atmosphere for, for example, maintenance. However, when the processing container is opened to the air atmosphere in the state in which TiCl₄ or TiF₄ is present therein, TiCl₄ or TiF₄ reacts with the moisture in the air atmosphere to generate HCl or HF. The HCl or HF not only causes a human injury, but also requires long-time evacuation after opening to the air atmosphere, which makes maintenance difficult.

Therefore, the plasma processing apparatus 1 according to the embodiment holds the liquid that adsorbs the byproducts in the area of the processing container 10 to which the byproducts generated by the plasma processing adhere. The liquid may have a property of adsorbing byproducts and a property of not volatilizing even in a vacuum atmosphere. As such a liquid, an ionic liquid may be exemplified.

[Holding State of Ionic Liquid]

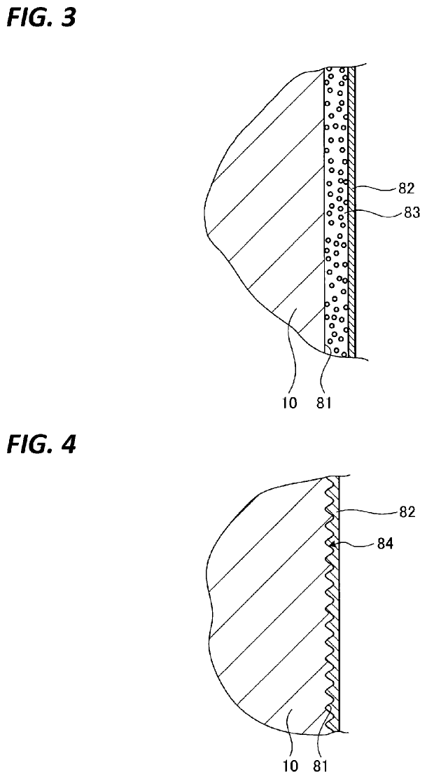

FIG. 3 is a view schematically representing an example of holding of an ionic liquid according to an embodiment. FIG. 3 illustrates an example in which the ionic liquid 82 is held on the wall surface 81 of the area of the processing container 10 to which byproducts adhere.

The ionic liquid 82 is held on the wall surface 81. As an example, as illustrated in FIG. 3, a liquid holding member 83 adheres to the wall surface 81 in the state in which the ionic liquid 82 is held by the liquid holding member 83. The liquid holding member 83 holds the ionic liquid 82 since the liquid holding member 83 is impregnated with the ionic liquid 82. As the liquid holding member 83, for example, a porous material such as, for example, paper or a sponge sheet may be used. As paper, for example, clean paper (dust-free paper) used for a clean room may be used. As the clean paper, for example, “Staculine” (trademark) manufactured by Sakurai Co., Ltd. may be mentioned.

For example, when paper such as clean paper is used as the liquid holding member 83, since the paper has appropriately fine holes, the ionic liquid 82 is capable of being appropriately held in the holes. In addition to this, since one pore is widely communicated with other pores in the paper in the form of a mesh, the pores may be filled with the ionic liquid 82 and a sufficient amount of byproducts may be taken into the inner pores by taking the byproducts attached to the ionic liquid 82 on the surface of the paper into the inside of the paper. In addition, since the paper is flexible, it is possible to easily process the paper into any shape, and it is possible to attach the paper along the inner wall of the processing container 10 having a complicated shape. For example, it is also possible to easily adhere the paper impregnated with the ionic liquid 82 over the entire inner wall of the processing container 10.

Furthermore, the paper impregnated with the ionic liquid 82 may be easily attached directly to the wall surface 81 using an adsorption force by a capillarity which absorbs the ionic liquid 82, and the paper may be easily peeled off from the wall surface 81, the ionic liquid 82 may be easily handled. Since the paper impregnated with the ionic liquid 82 is lightweight and has an adsorption amount sufficiently, a fixing structure for fixing the liquid holding member 83 to the wall surface 81 is not necessary, and the liquid holding member 83 may be easily attached. In the case where a lightweight sponge sheet is used as the liquid holding member 83, the sponge sheet may be attached to the wall surface 81 using the adsorption force by the viscosity of the ionic liquid 82.

FIG. 4 is a view schematically illustrating another example of holding of an ionic liquid according to an embodiment. FIG. 4 illustrates an example in which the ionic liquid 82 is held on the wall surface 81 of the area of the processing container 10 to which byproducts adhere. In FIG. 4, instead of using the liquid holding member 83, the surface of the wall surface 81 of the processing container 10 is provided with irregularities 84 capable of properly holding the ionic liquid 82 without allowing the ionic liquid to flow. For example, by applying the ionic liquid 82 to the wall surface 81 provided with the irregularities 84, the ionic liquid 82 adhering to the irregularities 84 is held. The irregularities 84 are formed to have a predetermined surface roughness by various surface treatments such that the ionic liquid 82 is held at an appropriate amount, for example, an appropriate film thickness on the wall surface 81 of the processing container 10.

The ionic liquid 82 may be provided over the entire area to which the byproducts adhere using the liquid holding member 83 or the irregularities 84. In this manner, the byproducts generated into the processing container 10 are capable of being adsorbed well by the ionic liquid 82.

In the plasma processing apparatus 1, the liquid holding member 83 may be provided on a portion of the wall surface 81, and the irregularities 84 may be provided on a portion of the wall surface 81 depending on the position of the wall surface 81 of the processing container 10. For example, the liquid holding member 83 impregnated with the ionic liquid 82 may attached to a portion where the application of the ionic liquid 82 is relatively difficult due to, for example, the shape of the wall surface 81, and the ionic liquid 82 may be applied to the irregularities 84 provided in the portion where the application of the ionic liquid 82 is relatively easy.

Here, in the plasma processing apparatus 1, the processing container 10 may be heated using, for example, a heater, in order to prevent adhesion/deposition of, for example, byproducts. However, in the plasma processing apparatus 1, even if the processing container 10 is heated, byproducts may be easily accumulated in the portion where the temperature is relatively low due to, for example, temperature unevenness. In addition, in the plasma processing apparatus 1, it is possible to remove byproducts by, for example, plasma cleaning as long as the plasma can reach. However, the byproducts are easily accumulated in a portion where the plasma does not reach. For example, since the plasma does not reach a space below the baffle plate 50 or a space between the inner wall of the processing container 10 and the deposition shield 71, byproducts are easily accumulated below the baffle plate 50 or between the inner wall of the processing container 10 and the deposition shield 71. In the plasma processing apparatus 1 according to the embodiment, the ionic liquid may be held in an area where byproducts are easily accumulated. For example, the ionic liquid may be held on the wall surface of the processing container 10 below the baffle plate 50 or between the wall surface of the processing container 10 and the deposition shield 71.

[Example of Ionic Liquid]

Since the ionic liquid 82 has the property of not volatilizing even in a vacuum atmosphere, it is possible to make the ionic liquid 82 remain as a liquid in the vacuum atmosphere in the processing container 10. Therefore, the volatile component or the decomposition product of the ionic liquid 82 does not adhere to a semiconductor wafer W transported in the processing container 10 in the plasma processing apparatus 1. In addition, as the ionic liquid 82, one that is hydrophobic, water-insoluble, and non-reactive with water (moisture) may be used.

The ionic liquid 82 is capable of preventing the uptake of water into the ionic liquid 82 by having a hydrophobicity, a water-insolubility, and a property not to react with water. The inside of the processing container 10 may be exposed to the air atmosphere due to, for example, maintenance. In such a case, the water contained in the air atmosphere may be taken into the ionic liquid 82, and when the inside of the processing container 10 is evacuated, the water in the ionic liquid 82 may be released into the vacuum atmosphere, thereby affecting the degree of vacuum inside the processing container 10. In addition, depending on the speed at which the moisture taken into the ionic liquid 82 is released from the ionic liquid 82, the time required for evacuation in the processing container 10 may be extended. Furthermore, when the water released from the ionic liquid 82 adheres to the semiconductor wafer W, the characteristics of the semiconductor wafer W may be changed. In addition, when water is taken into the ionic liquid 82, the viscosity (viscosity coefficient) of the ion liquid 82 changes, which may make it difficult to properly maintain the state of being held on the wall surface 81. For example, when the viscosity of the ionic liquid 82 decreases, the ionic liquid 82 disposed on the wall surface 81 sags downward due to gravity.

In addition, since the inside of the processing container 10 may be exposed to the air atmosphere, it is desirable to avoid the use of the ionic liquid 82 that chemically reacts with the water contained in the air atmosphere. For example, an ionic liquid 82 using PF₆— or BF₄— as an anion generate hydrofluoric acid (HF) by reacting with water. Thus, in consideration of the influence on the environment and human body and from the viewpoint of securing the durability of the processing container 10, it is desirable to avoid the use of such an ionic liquid.

Therefore, the ionic liquid 82 is preferably made to be hydrophobic, water-insoluble, and non-reactive with water. This makes it possible to suppress a decrease in degree of vacuum in the processing container 10. In addition, it is possible to suppress the holding power, which is maintained by the liquid holder, from decreasing as the viscosity of the ionic liquid 82 decreases. Further, by avoiding the reaction between the ionic liquid 82 and water, it is possible to suppress the influence on the environment and the human body while properly securing the durability of the processing container 10.

It is preferable that the ionic liquid 82 be a liquid in a temperature range from the room temperature to the temperature at the time of a plasma processing. In order to properly secure the optimum range (process window) of plasma processing, it is preferable that the ionic liquid 82 have a melting point as low as possible, and that the ionic liquid 82 have a boiling point as high as possible.

As a very suitable ionic liquid 82, at least one of, for example, methyltrioctylammonium thiosalicylate, trihexyltetradecylphosphonium bis(2-ethylhexyl)phosphate, methyltrioctylammonium bis(trifluoromethylsulfonyl)imide, 1-ethyl-3-methylimidazolium bis(trifluoromethylsulfonyl)imide, 1-butyl-3-methylimidazolium bis(trifluoromethylsulfonyl)imide, 1-hexyl-3-methylimidazolium bis(trifluoromethylsulfonyl)imide, 1-methyl-1-propylpyrrolidinium bis(trifluoromethylsulfonyl)amide is used.

For example, methyltrioctylammonium bis(trifluoromethylsulfonyl)imide can be easily wiped off with isopropyl alcohol (IPA), a commonly used cleaning material in the industry.

The ionic liquid 82 having a high viscosity is capable of being easily held on the wall surface 81 of the processing container 10. Meanwhile, the ionic liquid 82 having a low viscosity may be easily held on the wall surface 81 of the processing container 10 using the liquid holding member 83 described above or providing irregularities 84 on the wall surface 81 of the processing container 10. The ionic liquid 82 is less deteriorated by plasma at a place where the plasma does not reach. Accordingly, it is applicable that the ionic liquid 82 is coated on the wall surface 81 of the processing container 10 at maintenance and is removed and recoated at the next maintenance.

Multiple types of ionic liquids 82 having different viscosities may be disposed on the wall surface 81 of the processing container 10 using the liquid holding member 83. For example, multiple types of ionic liquids 82 having different viscosities may be disposed using the liquid holding member 83 depending on a distribution state in which byproducts in the atmosphere in the processing container 10 are scattered.

As described above, in the plasma processing apparatus 1 according to the present embodiment, the liquid that adsorbs byproducts is held in the area of the processing container 10 to which the byproducts generated by the plasma processing adhere. Thus, in the plasma processing apparatus 1, it is possible to suppress the generation of harmful gases.

Further, in the plasma processing apparatus 1, the liquid that adsorbs the byproducts is held in an area in the processing container 10 where the plasma does not reach. Thus, in the plasma processing apparatus 1, it is possible to adsorb, by the liquid, the byproducts adhering to the area where the plasma cleaning cannot be performed.

In the plasma processing apparatus 1, the liquid that adsorbs byproducts may be held at least on the exhaust port 46 side of the baffle plate 50 provided at the upstream side of the exhaust port 46 of the processing container 10 and between the deposition shield 71 provided along the inner wall of the processing container 10 and the inner wall of the processing container 10. In this manner, in the plasma processing apparatus 1, it is possible to adsorb, with the liquid, the byproducts adhering to the exhaust port 46 side of the baffle plate 50 or between the deposition shield 71 and the inner wall of the processing container 10.

The liquid that adsorbs the byproducts is the ionic liquid 82. In this manner, in the plasma processing apparatus 1, it is possible to adsorb the byproducts generated during the plasma processing with the ionic liquid 82.

The ionic liquid 82 is hydrophobic. This makes it possible to prevent the uptake of water into the ionic liquid 82.

In addition, the ionic liquid 82 is water-insoluble and non-reactive with water. As a result, it is possible to suppress the decrease in viscosity of the ionic liquid 82 due to the reaction with water.

The ionic liquid 82 is at least one of methyltrioctylammonium thiosalicylate, trihexyltetradecylphosphonium bis(2-ethylhexyl)phosphate, methyltrioctylammonium bis(trifluoromethylsulfonyl)imide, 1-ethyl-3-methylimidazolium bis(trifluoromethylsulfonyl)imide, 1-butyl-3-methylimidazolium bis(trifluoromethylsulfonyl)imide, 1-hexyl-3-methylimidazolium bis(trifluoromethylsulfonyl)imide, 1-methyl-1-propylpyrrolidinium bis(trifluoromethylsulfonyl)amide. In this manner, it is possible to adsorb byproducts generated during the plasma processing.

In addition, the plasma processing apparatus 1 is provided with a liquid holding member 83 for holding the liquid that adsorbs byproducts in the area to which the byproducts adhere. In this manner, in the plasma processing apparatus 1, it is possible to hold the liquid that adsorbs byproducts in the area to which the byproducts adhere using the liquid holding member 83.

The liquid holding member 83 is formed of a porous material. Thus, the liquid holding member 83 is capable of properly holding the liquid that adsorbs the byproducts in the pores. In addition, the liquid holding member 83 is capable of taking in a sufficient amount of byproducts in pores therein.

The liquid holding member 83 is paper or a sponge sheet. Thus, the liquid holding member 83 is capable of properly holding the liquid that adsorbs byproducts. In addition, the liquid holding member 83 is capable of taking in a sufficient amount of byproducts.

In addition, the plasma processing apparatus 1 is provided with irregularities 84 for holding the liquid that adsorbs byproducts in the area to which the byproducts adhere. In this manner, in the plasma processing apparatus 1, it is possible to hold the liquid that adsorbs byproducts in the area to which the byproducts adhere using the irregularities 84.

For example, in the embodiment, although the case where the object to be processed is a semiconductor wafer has been described as an example, the present disclosure is not limited thereto. The object to be processed may be another substrate such as a glass substrate.

In the embodiment, the substrate processing apparatus is the plasma processing apparatus 1 and the case where plasma etching is performed as a substrate processing has been described as an example, but the present disclosure is not limited thereto. The substrate processing apparatus may be any apparatus that performs a substrate processing that generates byproducts from which harmful gases are generated.

In the embodiment, as a byproduct which becomes a source of a harmful gas, a substance which becomes a source of a harmful gas by reacting with water such as, for example, TiCl₄ or TiF₄, has been described as an example. However, a byproduct which becomes a source of a harmful gas may be a substance that generates the harmful gas by reacting with a substance other than water, or a substance that generates the harmful gas without reacting with other substances.

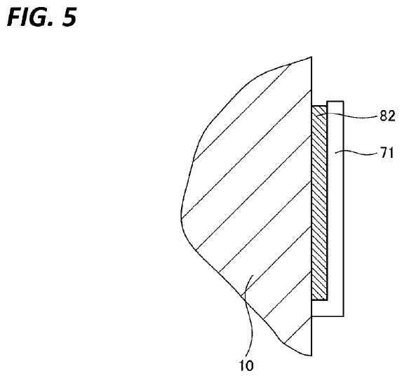

In the embodiment, the case where the liquid holding member 83 or the irregularities 84 hold a liquid that adsorbs byproducts such as, for example, the ionic liquid 82 in the processing container 10 has been described as an example. However, the present disclosure is not limited thereto. The liquid that adsorbs byproducts may be held in a sealed container so as not to leak. FIG. 5 is a view schematically illustrating another example of holding of an ionic liquid according to an embodiment. In FIG. 5, the lower portion of a gap between the inner wall of the processing container 10 and a deposition shield 71 is sealed, and the gap is filled with the ionic liquid 82. In this manner, in the plasma processing apparatus 1, it is possible to adsorb the byproducts generated during the plasma processing with the ionic liquid 82. In addition, since the plasma is shielded by the deposition shield 71, it is possible to suppress the deterioration of the ionic liquid 82.

According to the present disclosure, it is possible to suppress the generation of a harmful gas.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

What is claimed is:

1. A substrate processing apparatus comprising:
a processing container configured to accommodate a substrate and to perform a substrate processing that generates a byproduct that becomes a source of a harmful gas; and
a liquid holder provided in an area of the processing container where the byproduct generated by the substrate processing adheres and configured to hold a liquid that adsorbs the byproduct.

2. The substrate processing apparatus according to claim 1, wherein the substrate processing is an etching processing that etches the substrate by generating plasma while supplying a processing gas into the processing container.

3. The substrate processing apparatus according to claim 2, wherein the liquid holder is provided in an area where the plasma in the processing container does not reach.

4. The substrate processing apparatus according to claim 2, wherein the processing container has a baffle plate provided on an upstream side of an exhaust port that evacuates an inside of the processing container to suppress inflow of the plasma to the exhaust port, and a protective member provided along an inner wall of the processing container, and
the liquid holder is provided on an exhaust port side of the baffle place or between the inner wall of the processing container and the protective member.

5. The substrate processing apparatus according to claim 1, wherein the liquid is an ionic liquid.

6. The substrate processing apparatus according to claim 5, wherein the ionic liquid is hydrophobic.

7. The substrate processing apparatus according to claim 5, wherein the ionic liquid is water-insoluble and non-reactive with water.

8. The substrate processing apparatus according to claim 5, wherein the ionic liquid is at least one selected from the group consisting of: methyltrioctylammonium thiosalicylate, trihexyltetradecylphosphonium bis(2-ethylhexyl)phosphate, methyltrioctylammonium bis(trifluoromethylsulfonyl)imide, 1-ethyl-3-methylimidazolium bis(trifluoromethylsulfonyl)imide, 1-butyl-3-methylimidazolium bis(trifluoromethylsulfonyl)imide, 1-hexyl-3-methylimidazolium bis(trifluoromethylsulfonyl)imide, and 1-methyl-1-propylpyrrolidinium bis(trifluoromethylsulfonyl)amide.

9. The substrate processing apparatus according to claim 1, wherein the liquid holder is a liquid holding member formed of a porous material.

10. The substrate processing apparatus according to claim 9, wherein the liquid holding member is either a paper or a sponge sheet.

11. The substrate processing apparatus according to claim 1, wherein the liquid holder is an inner wall of the processing container which has an irregularity to hold the liquid.

12. A substrate processing method comprising:
providing a substrate processing apparatus including a processing container configured to accommodate a substrate and perform a substrate processing that generates a byproduct that becomes a source of harmful gas;
providing a liquid holder in an area of the processing container where a byproduct generated by the substrate processing adheres;
providing a liquid that adsorbs the byproduct in the processing container; and
disposing the substrate in the processing container and performing the substrate processing thereby allowing the liquid in the liquid holder to adsorb the byproduct.
